(19) United States
(12) Patent Application Publication
(10) Pub. No.: US 2010/0025710 A1
(43) Pub. Date: Feb. 4, 2010

(54) Semiconductor device and fabrication method thereof

(75) Inventors: Shigeru Yamada, Tokyo (JP); Makoto Terui, Jamannshi (JP); Yoshimi Egawa, Tokyo (JP); Shinji Ohuchi, Tokyo (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/461,051

(22) Filed: Jul. 30, 2009

(30) Foreign Application Priority Data
Aug. 1, 2008 (JP) 2008-200010

(51) Int. Cl. H01L 33/00

(52) U.S. Cl. 257/98; 257/99; 257/E33.062; 257/E33.066; 257/E33.056

(57) ABSTRACT

There is provided a semiconductor device including: a semiconductor chip having a penetrating electrode penetrating through from a first main surface of the semiconductor chip to a second main surface on the opposite side thereof, a photoreceptor portion formed on the first main surface, and a first wire at a periphery of the photoreceptor portion; a light transmitting chip adhered to the first main surface at the periphery of the light transmitting chip, with a bonding layer interposed between the light transmitting chip and the first main surface, the light transmitting chip covering the light transmitting chip; and a light blocking resin layer formed only on the side surfaces of the light transmitting chip and the bonding layer.

### CROSS-REFERENCE TO RELATED APPLICATION

This application claims priority under 35 USC 119 from Japanese Patent Application No. 2008-200010 filed on Aug. 1, 2008, the disclosure of which is incorporated by reference herein.

### BACKGROUND

1. Technical Field

The present invention relates to a semiconductor device and to a fabrication method thereof. In particular the present invention relates to a semiconductor device structure having a semiconductor chip, such as a sensor module, and a protection glass.

2. Related Art

Existing known semiconductor devices having a semiconductor chip, such as a sensor module, and a protection glass include: a structure with a light blocking film formed on the side surfaces of an optical member provided on microlenses of a semiconductor chip (see Japanese Patent Application Laid-Open (JP-A) No. 2007-142058); a structure having a covering layer formed on a semiconductor chip having a circuit portion including a photoreceptor element, with a sealing resin formed to the whole of the semiconductor chip and on the side surfaces of the covering layer (see JP-A No. 2004-363380); and a solid state image capture device structure of a wafer-level chip sized package provided with a cover glass, supported with interposed spacers, for covering and protecting a photoreceptor portion of an image sensor chip, and with penetrating wires penetrating through the image sensor chip (see JP-A No. 2007-184680).

In the technology of JP-A No. 2007-142058 a light blocking film is provided for each of the individual optical members, and each of the individual optical members is adhered to each individual semiconductor chip one at a time, consequently this leads to many manufacturing processes for each image capture element, and a structure enabling the elimination of processing is desired.

In the technology of JP-A No. 2004-363380 after making external terminals of the back surface of the semiconductor chip in high pillar shapes, a sealing layer is formed covering the back surface and side surfaces of the semiconductor device, and bump electrodes are formed on top of the external terminals after the sealing layer has been polished, leading to a semiconductor device that is thick overall. In addition, various processes are added in order to lead the bump electrodes from the pillar shaped external terminals, giving rise to many manufacturing processes. A thin semiconductor device is therefore desired, and a structure enabling a reduction in processing is also desired. Cutting must be made in the dicing process with a blade appropriate for both a glass covering layer and a semiconductor wafer (referred to sometimes below simply as wafer), with there being fewer options for blade choice. Also, in comparison to when a blade appropriate to a covering layer is used, with a blade appropriate for both materials there is concern of breakage and defects etc. occurring at the cut face of the covering layer and also of affecting the top surface of the covering layer onto which light is incident. When the side surfaces of a semiconductor device are cut at an angle this also limits the yield of semiconductor devices obtained from one semiconductor wafer.

In the solid state image capture device of JP-A No. 2007-184680, an anti-reflection layer is formed to the back surface of an image sensor to prevent reflection of light that has been transmitted through the image sensor during image capture, and incidence thereof onto the photoreceptor. However, since light enters from the side surfaces of the above cover glass, there is the problem that desired characteristics are not obtained. In addition, the cover glass and the semiconductor wafer are partitioned using dicing technology, requiring a wide cut width by a blade suited to both materials, and therefore the scribe line width of the semiconductor chip needs to be set wide, with an issue being that the effective number of elements on a semiconductor wafer is reduced. In addition, technical problems arise, such as defects to corner portions of the cover glass during dicing and defects readily occurring during handling, reducing the yield rate, or dicing stress acting on a spacer bonding portion interface reducing reliability such as water resistance.

### SUMMARY

The present invention is made in consideration of the above technical problems and provides a semiconductor device with suppressed number of fabrication processes and obtaining raised yields of the semiconductor device, and a fabrication method thereof.

According to an aspect of the present invention, there is provided a semiconductor device including:

a semiconductor chip having a penetrating electrode penetrating through from a first main surface of the semiconductor chip to a second main surface on the opposite side thereof, a photoreceptor portion formed on the first main surface, and a first wire at a periphery of the photoreceptor portion;

a light transmitting chip adhered to the first main surface at the periphery of the light transmitting chip, with a bonding layer interposed between the light transmitting chip and the first main surface, the light transmitting chip covering the light transmitting chip; and

a light blocking resin layer formed only on the side surfaces of the light transmitting chip and the bonding layer.

Further, according to another aspect of the present invention, there is provided a semiconductor device fabrication method including:

forming a bonded body from a semiconductor wafer and a light transmitting substrate, the semiconductor wafer having a plurality of circuit regions thereon, the circuit regions each including a penetrating electrode penetrating through from a first main surface of the semiconductor wafer to a second main surface on the opposite side thereof, a photoreceptor portion formed on the first main surface, and a first wire at a periphery of the photoreceptor portion, and the light transmitting substrate adhered at the periphery of each of the circuit regions with a bonding layer interposed therebetween, and the light transmitting substrate covering the photoreceptor portion;

forming a groove in the light transmitting substrate of the bonded body so as to reach the bonding layer, and filling the groove with light blocking resin to form a light blocking resin layer;

severing the light blocking resin layer with a width narrower than the groove width, dividing the bonded body into a plurality of semiconductor chips and respective light transmitting chips joined by a bonding layer, leaving the light blocking resin layer remaining formed only on the side surfaces of the light transmitting chip and the bonding layer.

In the another aspect, the groove may be formed from the light blocking resin layer side as far as the bonding layer such that the light blocking resin layer has an outside surface that is orthogonal to the first main surface and the second main surface, and the outside surface is in the same flat plane as a side surface of the semiconductor chip.

Further, the groove may formed so as to divide the bonding layer such that the light blocking resin layer has an outside surface that is orthogonal to the first main surface and the second main surface, and the outside surface is parallel to a side surface of the light transmitting chip and to a side surface of the semiconductor chip.

In the another aspect, forming the bonded body may include:

preparing the light transmitting substrate, forming the bonding layer on at least one of the light transmitting substrate and the first main surface of the semiconductor wafer so as to surround the photoreceptor portions on the semiconductor wafer, and adhering the light transmitting substrate and the semiconductor wafer with the bonding layer;

grinding away the semiconductor wafer, from the opposite side to that of the first main surface of the semiconductor wafer to which the light transmitting substrate is attached, so as to form the second main surface;

forming the penetrating electrodes so as to penetrate through the semiconductor wafer from the second main surface to the first wires of the first main surface.

The semiconductor device fabrication method of the present invention may further include forming second wires on the second main surface of the semiconductor wafer so as to be connected to the penetrating electrodes.

The semiconductor device fabrication method of the present invention may further include forming a metal pad at a portion at the end of the penetrating electrodes on the first main surface side.

In the semiconductor device structure of the present invention, the light blocking resin layer is stuck only to the side surfaces of the light transmitting chip and the bonding layer, therefore enabling a semiconductor device to be formed with a thin overall structure, while maintaining reliability, such as in water resistance. The present invention enables a more compact semiconductor device in comparison to the thick semiconductor device in the technology of JP-A No. 2004-363380 above that has resin also formed to the back surface of the semiconductor chip and forms the external terminals after forming posts and raising the electrodes. The structure of the present invention is also equipped with penetrating electrodes and so the mounting surface area becomes more narrow, enabling a more compact semiconductor device, in comparison to the technology of JP-A No. 2007-142058 in which a light blocking film is formed to the side surfaces of an optical member.

In addition, in the fabrication method of the present invention, grooves are formed in the dicing regions, and the light blocking resin is only injected therein, enabling formation while suppressing the cost. According to the present invention, there is a dramatic reduction in processing in comparison to the technology of JP-A No. 2004-363380 above in which a resin layer is formed to the entire semiconductor chip after grooves are formed in the dicing regions, and post forming processing is added for leading out electrodes from the resin layer.

In the fabrication method of the semiconductor device according to the present invention, the groove may be formed from the light blocking resin layer side as far as the bonding layer such that the light blocking resin layer has an outside surface that is orthogonal to the first main surface and the second main surface, and the outside surface is in the same flat plane as a side surface of the semiconductor chip. Namely, according to the present invention, since the light blocking resin layer is configured only covering the side surfaces of the light transmitting chip and not covering the side surfaces of the semiconductor chip, a compact device is enabled in which it is possible to make the size of the device mounting surface area the same as the size of the semiconductor chip. In addition, according to the present invention, only the light transmitting substrate portion is cut, without cutting the semiconductor wafer, in groove forming, and so it is possible to select a blade appropriate for the light transmitting substrate. With regard to this point, in the technology of JP-A No. 2004-363380 above, cutting must be made in the groove forming process with a blade appropriate for both a glass plate and a semiconductor wafer, limiting options for blade selection, however in the present invention there is no such limitation. Also, in comparison to when a blade appropriate to a glass plate is used, in the technology of JP-A No. 2004-363380 where a blade appropriate for both materials is used there is concern of breakage and defects etc. occurring in the cut face of the glass plate and also of affecting the top surface of the glass plate onto which light is incident.

In addition, according to the present invention, since only the light transmitting substrate portion is cut, without cutting the semiconductor wafer, in groove forming, in comparison to the technology of JP-A No. 2004-363380 above, the effective number of semiconductor devices obtained from a single semiconductor wafer can be increased, and yield is improved.

In the semiconductor device fabrication method of the present invention, the groove may be formed so as to divide the bonding layer such that the light blocking resin layer has an outside surface that is orthogonal to the first main surface and the second main surface, and the outside surface is parallel to a side surface of the light transmitting chip and to a side surface of the semiconductor chip. Namely, in the structure of this exemplary embodiment, since the light blocking resin layer is stuck only to the side surfaces of the light transmitting chip and to the bonding layer between the light transmitting substrate and the semiconductor wafer, it is possible to save on material for the light blocking resin layer while maintaining reliability, such as in water resistance etc.

In the semiconductor device fabrication method according to the present invention, forming the bonded body may include: forming the bonding layer on at least one of the light transmitting substrate and/or the first main surface of the semiconductor wafer so as to surround the photoreceptor portions on the semiconductor wafer, and sticking together the light transmitting substrate and the semiconductor wafer with the bonding layer; grinding away the semiconductor wafer, from the opposite side to that of the first main surface of the semiconductor wafer to which the light transmitting substrate is attached, so as to form the second main surface; forming the penetrating electrodes so as to penetrate through the semiconductor wafer from the second main surface to the first wires of the first main surface.

Since the process for forming the bonded body of the light transmitting substrate and the semiconductor wafer, includes a process of grinding away the semiconductor wafer and reducing the thickness of the semiconductor wafer, the light transmitting substrate supports and maintains the strength of the semiconductor wafer, and contributes to avoiding damage to the semiconductor wafer during the processing the bonded body and during transportation thereof.

### BRIEF DESCRIPTION OF THE DRAWINGS

Exemplary embodiments of the present invention will be described in detail based on the following figures, wherein:

FIG. 1 is a cross-section showing a sensor module of a first exemplary embodiment of the present invention;

FIG. 2 is a cross-section showing a camera module including a sensor module of the first exemplary embodiment of the present invention;

FIG. 3 is a partial cross-section of a wafer showing a sensor module fabrication process of the first exemplary embodiment of the present invention;

FIG. 4 is a partial cross-section of a glass plate showing a sensor module fabrication process of the first exemplary embodiment of the present invention

FIG. 5 is a plan view of the back surface of a glass plate showing a sensor module fabrication process of the first exemplary embodiment of the present invention;

FIG. 6 is a partial cross-section of a bonded body of a glass plate and a wafer showing a sensor module fabrication process of the first exemplary embodiment of the present invention;

FIG. 7 is a partial cross-section of a bonded body of a glass plate and a wafer showing a sensor module fabrication process of the first exemplary embodiment of the present invention;

FIG. 8 is a partial cross-section of a bonded body of a glass plate and a wafer showing a sensor module fabrication process of the first exemplary embodiment of the present invention;

FIG. 9 is a partial cross-section of a bonded body of a glass plate and a wafer showing a sensor module fabrication process of the first exemplary embodiment of the present invention;

FIG. 10 is a partial cross-section of a bonded body of a glass plate and a wafer showing a sensor module fabrication process of the first exemplary embodiment of the present invention;

FIG. 11 is a partial cross-section of a bonded body of a glass plate and a wafer showing a sensor module fabrication process of the first exemplary embodiment of the present invention;

FIG. 12 is a partial cross-section of a bonded body of a glass plate and a wafer showing a sensor module fabrication process of the first exemplary embodiment of the present invention;

FIG. 13 is a partial cross-section of a bonded body of a glass plate and a wafer showing a sensor module fabrication process of the first exemplary embodiment of the present invention;

FIG. 14 is a partial cross-section of a bonded body of a glass plate and a wafer showing a sensor module fabrication process of the first exemplary embodiment of the present invention;

FIG. 15 is a cross-section showing a sensor module of a second exemplary embodiment of the present invention;

FIG. 16A to 16D are partial cross-sections of a bonded body of a glass plate and a wafer showing processes of sensor module fabrication of the second exemplary embodiment of the present invention;

FIG. 17 is a cross-section showing a camera module including a sensor module of the second exemplary embodiment of the present invention;

FIG. 18 is a cross-section showing a sensor module of a modified example of the first exemplary embodiment of the present invention; and

FIG. 19 is a cross-section showing camera module including a sensor module of a modified example of the first exemplary embodiment of the present invention.

### DETAILED DESCRIPTION

Explanation will now be given regarding details of a sensor module of a semiconductor device of an exemplary embodiment of the present invention, with reference to the attached drawings. It should be noted that in each of the drawings, where the same configuration element is shown in separate drawings the same reference number is allocated thereto, and detailed explanation thereof is omitted.

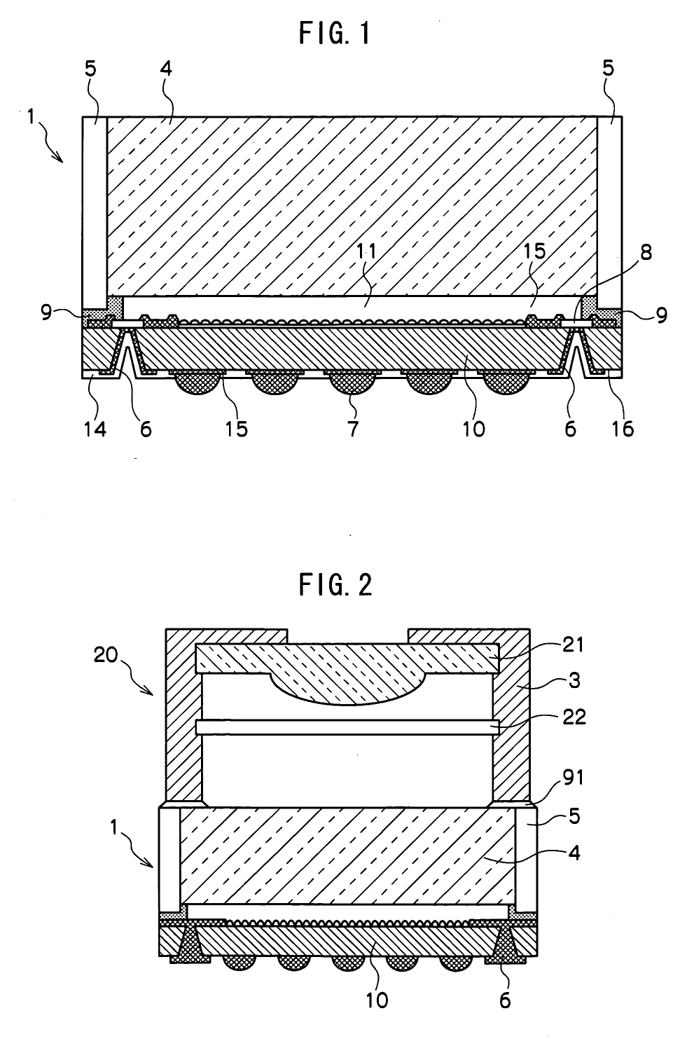

FIG. 1 is a cross-section of a sensor module of a first exemplary embodiment. A sensor module 1 is configured overall including a glass plate 4 that is a light transmitting chip, and a semiconductor chip 10, formed from silicon or the like, to which the glass plate 4 is attached by a bonding layer 9. A UV-curable or heat-curable material is employed as the material of the bonding layer 9.

A light blocking resin layer 5 is formed on the bonding layer 9, stuck onto the side surfaces of the glass plate 4.

A photoreceptor portion 11 including photoreceptor elements, such as CMOS sensors etc., is formed to a first main surface of the semiconductor chip 10 to which the bonding layer 9 is attached. On the photoreceptor portion 11, on-chip microlenses may be provided respectively mounted to photoelectric conversion elements. First wires 15 and metal pads 8 are formed, as a sensor circuit, on the first main surface around the periphery of the photoreceptor portion 11 of the semiconductor chip 10, the first wires 15 connected to the photoreceptor portion 11 and to the metal pads 8.

Second wires 15 and external terminals 7 are formed at specific positions on a second main surface (back surface) at the opposite of the semiconductor chip 10 to the side of the first main surface, with an insulating film 14 formed to portions thereof other than at the external terminals 7. The side surfaces of the semiconductor chip 10, which intersect with the first and the second main surfaces and define insulating portions, are exposed in the drawings, but an insulating coating treatment or the like may be performed thereto as required.

Penetrating electrodes 6 are provided in the semiconductor chip 10, below the metal pads 8 that are provided in the vicinity of the external periphery of the first main surface, and the penetrating electrodes 6 electrically connect the wires 15 of the first main surface to the wires 15 of the second main surface. By provision of the penetrating electrodes 6 penetrating through between the first and the second main surfaces, electrical connection to the photoreceptor portion 11 becomes possible through the second wires 15 on the back surface, instead of leading an electrical conductor around the side surfaces of the semiconductor chip. It should be noted that the penetrating electrodes 6 are electrically insulated from the material of the semiconductor chip 10 by an insulating film 16 that pre-covers the entire back surface of the chip and the inside surfaces of the through holes.

A space is provided between the glass plate 4 and the photoreceptor portion 11. However, this space may be filled with a resin of a light transmitting bonding material etc., as long as the glass plate 4 is bonded to the first main surface of the semiconductor chip 10 via the bonding layer 9 at least at the periphery of the photoreceptor portion 11.

The light blocking resin layer 5 that is stuck to the side surfaces of the glass plate 4 has a side surface that is stuck to the bonding layer 9 and that is in the same plane as the side surfaces of the semiconductor chip 10. Therefore, when the glass plate 4 is viewed from the front, the glass plate 4 configures a smaller surface area than that of the semiconductor chip 10. External light passes through the glass plate 4 from the front surface to the back surface, arrives at the main surface of the semiconductor chip 10, and is converted into an electrical signal by the photoreceptor portion 11. Incident light from the side surfaces of the glass plate 4 is blocked by the light blocking resin layer 5. Since there is a black colored light blocking resin layer 5 provided to the side surfaces, a sensor module capable of avoiding light entering from the side surfaces is obtained.

In this manner, since the light blocking resin layer 5 is formed to the side surfaces of the glass plate 4, the glass plate 4 becomes smaller, and incident light from the side surfaces, which produces noise, can be suppressed. In addition, local defects of the glass plate 4 during fabrication processes can be prevented, and by relieving stress at the bonding layer interface an improvement in the reliability can be achieved.

FIG. 2 is a cross-section of a camera module including a sensor module of the exemplary embodiment, in which the semiconductor chip 10 provided with penetrating electrodes 6 is attached to the glass plate 4. The camera module employs a structure in which a lens unit 20 is bonded to the glass plate 4 side of the sensor module 1 by use of a bonding member 91. The lens unit 20 has a structure in which a lens 21 and an IR ray blocking filter 22 are mounted parallel to each other at the inside of a hollow holder 3, in sequence from the front side. The end face around the periphery of an opening at the back side of the holder 3 is stuck to the peripheral edge portion of the glass plate 4 and to the light blocking resin layer 5, with the bonding member 91 interposed therebetween. The IR ray blocking filter 22 prevents generation of noise or the like from external IR rays incident on the photoreceptor portion 11. It should be noted that the IR blocking filter of the holder 3 can be omitted if the front face of glass plate 4 is covered by an IR ray blocking filter layer (not shown in the drawings), provided by vapor deposition or the like.

Explanation will now be given of an outline of the process flow in a fabrication method of the sensor module in the first exemplary embodiment, with reference to the substrate cross-sections etc. of the drawings.

Semiconductor Wafer Processing

In the semiconductor wafer state, plural sensor circuit regions are formed in a matrix shape on the front face of the semiconductor wafer by a semiconductor process.

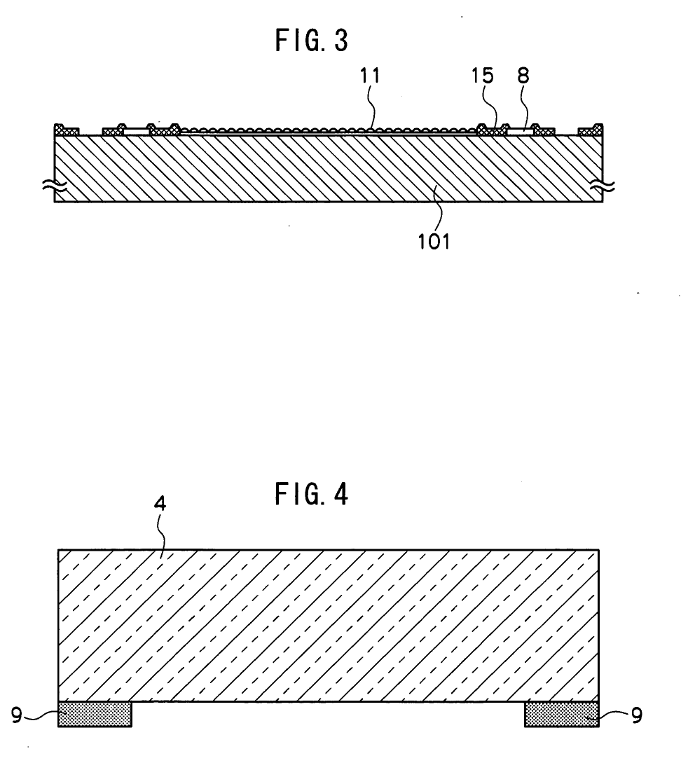

First, each of the sensor circuit regions is formed on a first main surface of a semiconductor wafer 101, as shown in FIG. 3, with the photoreceptor portion 11, and with the metal pads 8 formed around the periphery of the photoreceptor portion 11. A CMOS image sensor of an array of plural pixels (for example about 300,000) is formed in the photoreceptor portion 11. A microlens may be provided for each of the photoreceptor elements of the photoreceptor portion 11. In each of the pixels, several individual amplifiers, configured from CMOS (Complementary Metal-Oxide Semiconductor) transistors, are provided for each photoreceptor element (buried photodiode). A metal with excellent conducting properties, such as aluminum (Al) or the like, is employed for the metal pads 8.

Next, the first wires 15 are formed, connecting the photoreceptor portion 11 including the photoreceptor elements and the metal pads 8 around the periphery of the photoreceptor portion 11, then plural sensor circuit regions are formed in a matrix array on the first main surface, with lattice shaped spaces left therebetween for use as dicing regions.

Glass Plate Processing

A 300 to 500 μm thickness glass plate for protection of the same size as the semiconductor wafer described above is prepared.

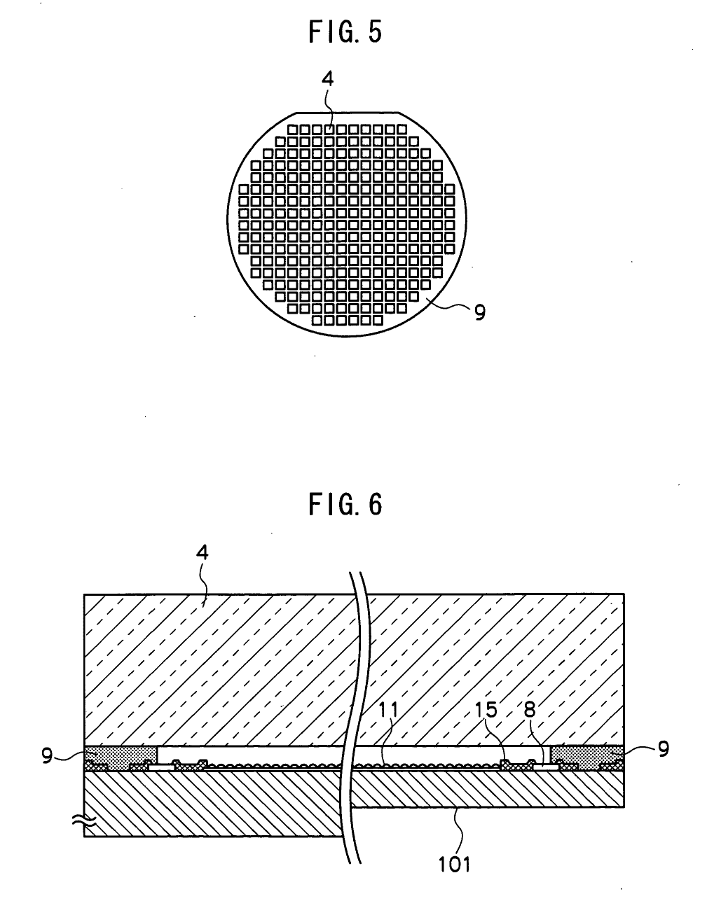

As shown in FIG. 4, the bonding layer 9 is formed on the back surface of the glass plate 4 at specific positions, as dicing regions, so that the bonding layer 9 surrounds each of the sensor circuit regions on the first main surface of the semiconductor wafer. A screen printing method or the like may be used, for example, for forming the film of the bonding layer 9, and as shown in FIG. 5 (a plan view of the back surface of the glass plate 4), the portions of the back surface of the glass plate 4 that are surrounded by the bonding layer 9 of lattice shape of the dicing regions, each correspond to a sensor circuit region. The bonding layer 9 is heat resistant, and a photosensitive polymer material such as, for example, benzocyclobutene (BCB), a polyimide or the like can be used for the bonding layer 9. The bonding layer 9 has a height of about 30 to about 70 μm.

The bonding layer 9 may, instead of being formed on the back surface of the glass plate 4, be formed by screen printing directly onto the first main surface of the wafer 101 in positions surrounding each of the sensor circuit regions.

Attachment Process

The glass plate 4 on which the bonding layer 9 has been formed is attached to the wafer 101 that has been formed with the sensor circuit regions.

The glass plate 4 and the wafer 101 are positionally aligned, as shown in FIG. 5, such that the photoreceptor portions 11 on the wafer 101 are surrounded by the lattice shaped bonding layer 9 formed on the back surface of the glass plate 4, light is irradiated thereon, and bonding is made due to photo-curing of the bonding layer 9. The bonding layer 9, joins the wafer 101 and the glass plate 4 together, while maintaining a specific separation distance therebetween, and the bonding layer 9 also exhibits a sealing function for the individual sensor circuit regions during a grinding process, penetrating electrode forming process, and dicing process, etc., as described below.

Grinding Process

The back surface of the wafer 101, which is integrated to the glass plate 4, is ground away, as shown in FIG. 6, so as, for example, to thin the thickness to a specific thickness, such as from a wafer thickness of 600 to 700 μm down to a thickness of 50 to 100 μm, and the second main surface of the wafer is flattened.

It should be noted that when the wafer 101 is of the specific thickness already, then the grinding process can be omitted.

Electrode Forming Process

Penetrating electrodes are formed, the second wires and external terminal are formed to the second main surface of the wafer 101 that has been integrated to the glass plate 4.

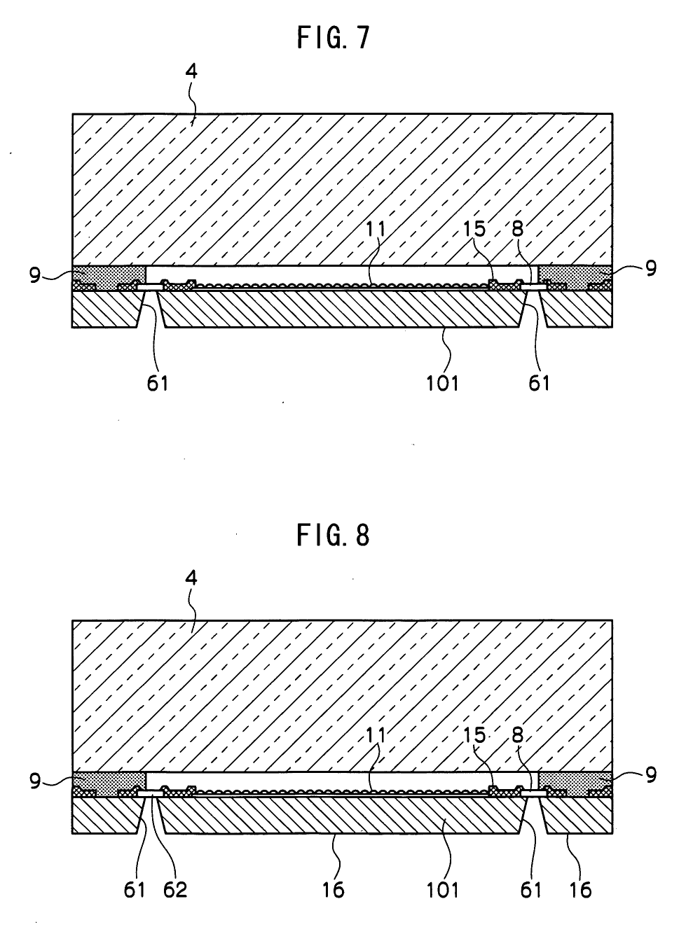

Through holes 61 (diameter=100 to 200 μm) are formed, as shown in FIG. 7, from the back surface (second main surface) of the wafer 101 up to each of the metal pads 8. The through holes 61, of size just slightly smaller than that of each of the metal pads 8, are formed through the back surface of the wafer 101 using a reactive ion etching (RIE) method at the positions of each of the metal pads 8 on the wafer 101. In the reactive ion etching method a mask (not shown in the drawings) of metal or resist is formed in advance to the second main surface of the wafer 101, the mask having openings at the portions where through holes 61 are to be formed. The Si wafer is then etched though the openings, for example, through an SiF₄ generating reaction in a mixed gas atmosphere containing CF₄, forming the through holes 61.

After this, as shown in FIG. 8, the insulating film 16, such as SiO₂, is formed to internal walls and the bottom portions (metal pads 8) of the through holes 61 and to the second main surface of the wafer 101, using a method such as CVD (Chemical Vapor Deposition). When this is carried out, the thickness of the insulating film 16 is formed so as to be thinner on the bottom portion of the through holes 61 (metal pads 8) than on the second main surface of the wafer 101. By so doing, openings 62 exposing the metal pads 8 are formed in the insulating film 16 at the bottom portions of the through holes 61 by performing reactive ion etching again, but the insulating film 16 is maintained on the inner walls of the through holes 61 and on the second main surface of the wafer 101.

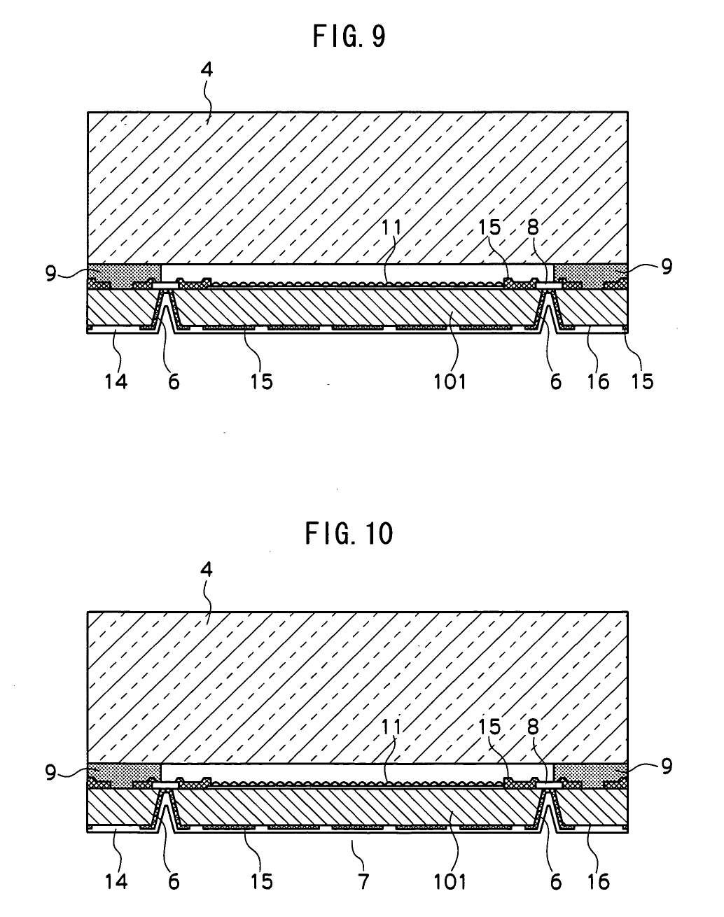

Then, a specific pattern mask (not shown in the drawings), having openings at the through holes where the metal pads 8 are exposed, at portions around these openings where the penetrating electrodes are to be formed, and at portions where the second wires 15 for connecting to the penetrating electrodes are to be formed, is formed in advance on the insulating film 16 at the second main surface of the wafer 101, and the second wires 15 and the penetrating electrodes 6 are formed, as shown in FIG. 9, using an electroplating method.

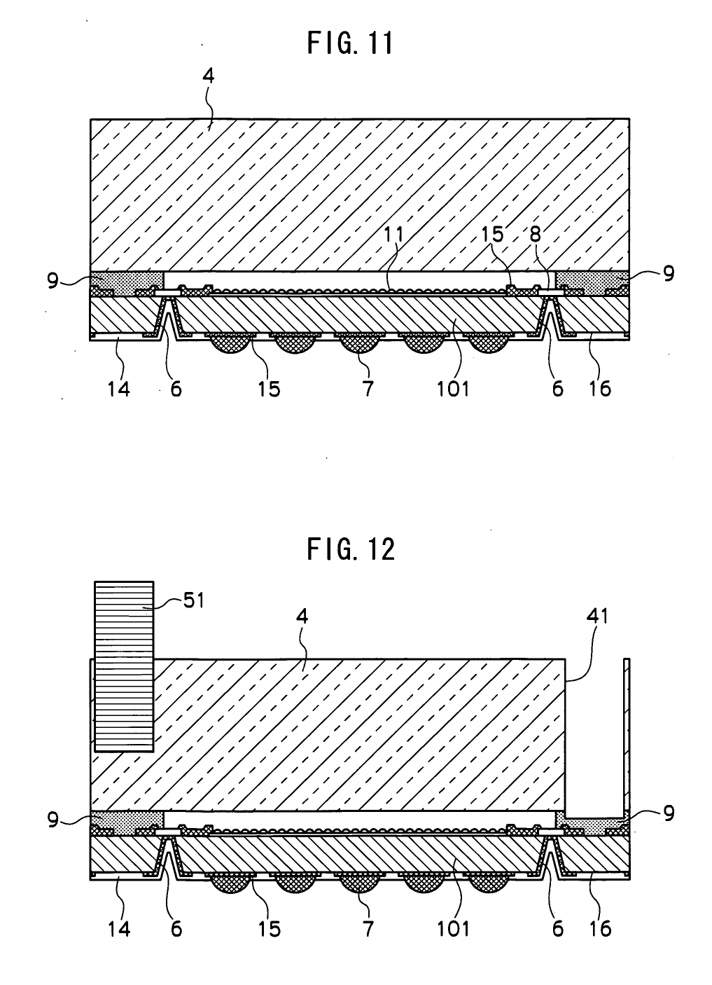

Then, as shown in FIG. 10, the insulating film 14 is applied to the entire back surface of the wafer 101, a photolithography process is executed to pattern such that the electrodes are exposed at portions to be formed with the external terminals 7 for connecting to external circuits, and then a solder paste is applied by a screen printing method onto the exposed electrodes on the back surface of the wafer 101 and reflow carried out. Remaining flux is then removed and, as shown in FIG. 11, the external terminals 7 are formed. It should be noted that a backing metal film (not shown in the drawings) may be formed prior to forming the external terminals 7.

Materials that may be used for the insulating film 14, other than Si0₂, include SiN, and PI (polyimide); materials that may be used for the wires include one or more conductive material selected from Cu, Al, Ag, Ni, Au etc.; and materials that may be used for the external terminals 7 include SnAg and NiAu.

Light Blocking Resin Layer Forming Process

As shown in FIG. 12, grooves 41 are formed in the dicing regions with a blade dicing method (or laser method), by only cutting the glass plate 4 into specific sized portions. The width of the cut (blade thickness) is preferably about 60 to 100 μm, since it is necessary to cut again in a later process. For example, cutting the glass plate 4 and part way through the bonding layer 9 with a dicing blade 51 from the glass plate 4 side.

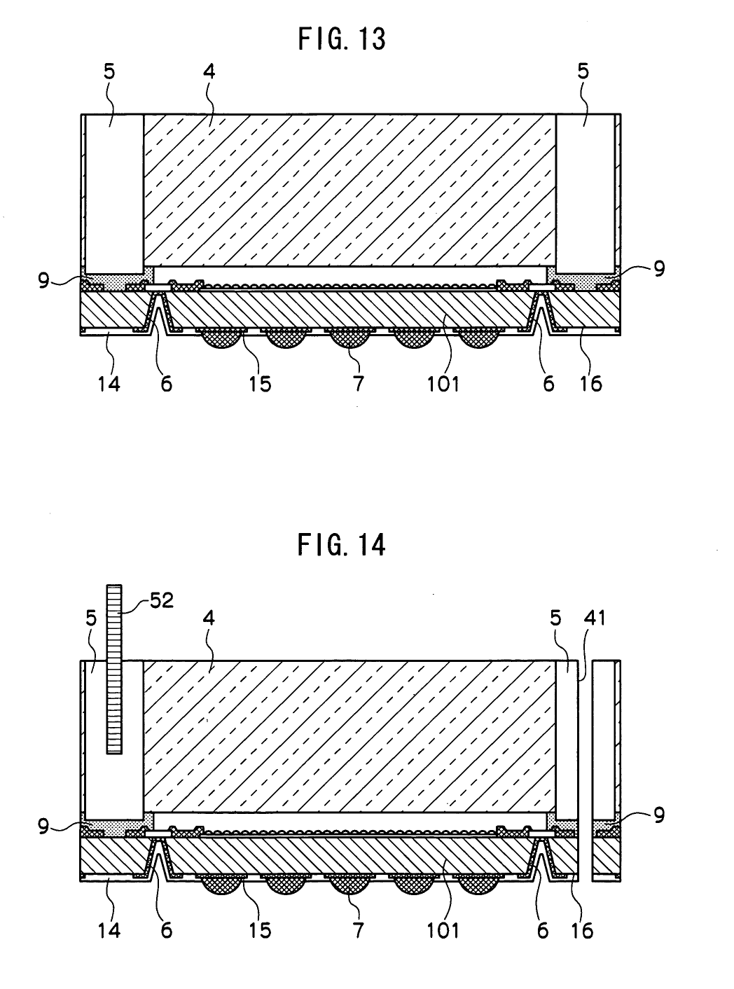

Next, as shown in FIG. 13, light blocking resin is injected into the cut groove portions using a printing method or a dispensing method, forming the light blocking resin layer 5. Materials for use as the light blocking resin layer 5 include polymer resins, such as epoxy resins, into which has been mixed black pigments such as carbon black, triiron tetroxide etc. Other dark colored pigments than black that exhibit light blocking properties can also be used.

Dicing Process

As shown in FIG. 14, the wafer 101 that has been integrated to the glass plate 4 is partitioned into individual sensor modules along the center of the light blocking resin layer 5 in the thickness direction by a specific second dicing blade 52. Dicing tape (not shown in the drawings) is adhered to the bonded body, of the glass plate and the wafer, on the wafer 101 side of the bonded body, mounted to a dicing apparatus, and dicing executed. In this process the second dicing blade is set so as to be able to cut a narrower width groove to that cut in the previous light blocking resin layer forming process, so that the light blocking resin layer 5 remains on the side surfaces of the glass plate 4.

The glass plate 4 and the wafer 101 are full cut to a specific size in the above manner, and a sensor module is obtained like the one shown in FIG. 1, formed from the glass plate 4 the bonding layer 9, and the semiconductor chip 10, with light prevented from entering in from the side surfaces of the glass plate 4 by use of the light blocking resin layer 5. It is sufficient as long as the glass plate 4 is formed with at least two sides smaller than the semiconductor chip 10, and there is no limitation to all of the side surfaces of the glass plate 4 being covered with the light blocking resin layer. The glass plate 4 and the wafer can also be full cut by a laser method instead of the blade dicing method, as long as a specific size can be achieved set such that the light blocking resin layer 5 remains on the side surfaces of the glass plate 4 after cutting has been performed.

According to the above exemplary embodiment, as well as an improvement being expected in the properties of the sensor module for suppressing incident light from the side surfaces of the glass plate 4 with the light blocking resin layer 5, since a wide width of the light blocking resin layer and a narrow the scribe line width of the semiconductor chip can be designed, a large effective number of chips can be obtained on a wafer, so an increase in yield and reduction in cost can also be expected. In addition, since the wide width light blocking resin layer is aligned with the scribe line width of the semiconductor chip 10 and cut finely, forming the light blocking resin layer at the same time as forming each of the sensor modules, the number of processes can be reduced. Also, since there is the resin layer formed to the side surfaces of the brittle glass, defects and breakage of the glass can also be prevented, and handling becomes easy. Furthermore, by providing the black colored light blocking resin layer 5 on the side surfaces of the glass plate 4 the provision of a separate guide cover for light blocking becomes unnecessary, and a cost reduction effect is obtained.

The above fabrication method is applicable to various sensor modules other than a CMOS sensor circuit, including: an image sensor circuit such as a CCD sensor circuit; an illumination intensity sensor circuit; a UV sensor circuit, an IR sensor circuit, or a temperature sensor circuit.

### Other Exemplary Embodiments

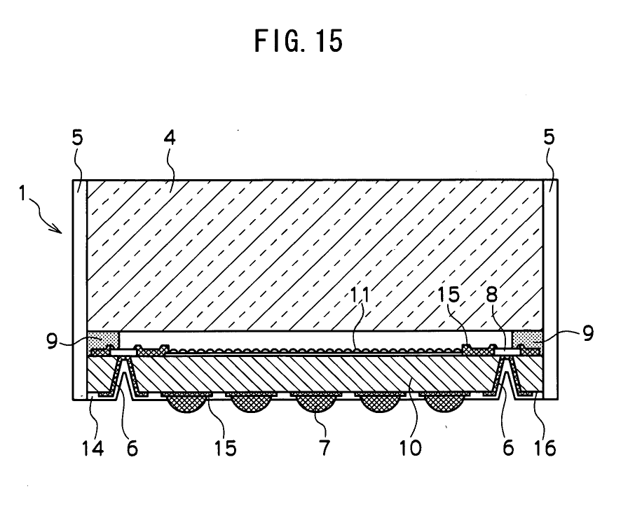

As a second exemplary embodiment a sensor module 1 is configured, as shown in FIG. 15, including a glass plate 4 that is a light transmitting chip, and a semiconductor chip 10 to which the glass plate 4 is attached by a bonding layer 9, and is similar to the sensor module of FIG. 1 except in having a structure in which a light blocking resin layer 5 is provided over the entire side surfaces of the glass plate 4 and the entire side surfaces of the semiconductor chip 10.

Processes prior to the light blocking resin layer forming process in the fabrication method of the sensor module are similar to those for producing the bonded body, of the glass plate 4 and the wafer 101, shown in FIG. 11 of the above first exemplary embodiment.

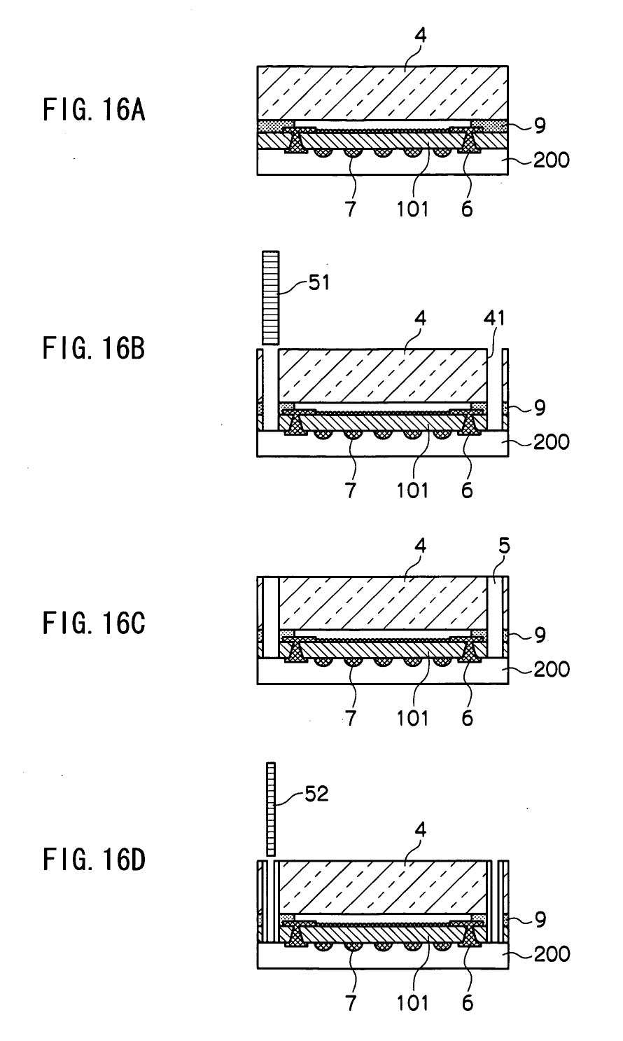

In the light blocking resin layer forming process, as shown in FIG. 16A, dicing tape 200 is adhered to the entire wafer surface of the bonded body of the glass plate 4 and wafer 101, mounting is made in a dicing apparatus, and dicing is executed.

As shown in FIG. 16B, the glass plate 4, the bonding layer 9, and the wafer 101 are full cut by a blade dicing method (or laser method) into a specific size from the glass plate 4 side all the way to the interface to the dicing tape 200 with the use of a dicing blade 51, so as to form grooves 41. The cut width is preferably about 60 to 100 μm since re-cutting is required at a subsequent process.

Next, as shown in FIG. 16C, a black colored resin is injected into the cut groove portions with a printing method or dispensing method, forming the light blocking resin layer 5, and reintegrating the bonded body.

Dicing Process

As shown in FIG. 16D, the glass plate 4 and the wafer 101 that have been integrated together with the light blocking resin layer 5 are parted with a specific second dicing blade 52, along the center of the light blocking resin layer 5 in the thickness direction thereof, into individual sensor modules. In this process the second dicing blade is set so as to be able to cut a narrower width groove to that cut in the previous light blocking resin layer forming process, so that the light blocking resin layer 5 remains on the side surfaces of the glass plate 4.

In the above manner, the glass plate 4 and the wafer 101 are full cut to a specific size, and a sensor module is obtained like the one shown in FIG. 15, formed from the glass plate 4, the bonding layer 9, and the semiconductor chip 10, with light prevented from intruding in from the side surfaces of the glass plate 4 by use of the light blocking resin layer 5,.

According to the second exemplary embodiment, light blocking ability is further raised by providing the light blocking resin layer 5 over the entirety of the side surfaces of the sensor module (the glass plate 4, the bonding layer 9 and the semiconductor chip 10), and water resistance of the interface and gas sealing properties thereof can also be raised.

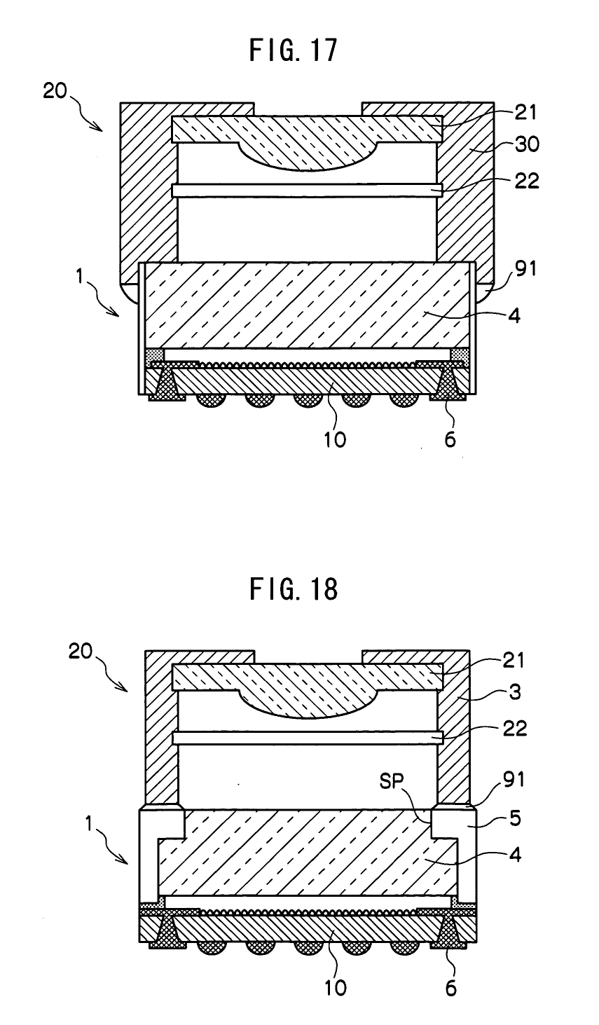

FIG. 17 is a cross-section of a camera module including the sensor module of the second exemplary embodiment in which the glass plate 4 is attached to the semiconductor chip 10 provided with penetrating electrodes 6. The camera module has a structure in which a lens unit 20 is bonded to the glass plate 4 side of the sensor module 1 by use of a bonding member 91. The lens unit 20 has a structure in which a lens 21 and an IR ray blocking filter 22 are mounted parallel to each other at the inside of a hollow holder 30, in sequence from the front side. The end face around the periphery of an opening at the back side of the holder 30 is stuck to the light blocking resin layer 5, with the bonding member 91 interposed therebetween. A recess 33 into which the sensor module fits is provided in the back surface of the hollow holder 30. The precision of separation between the lens 21 and the photoreceptor portion 11 along the lens axial direction can be raised by provision of the recessed structure. It should be noted that the sensor module of the second exemplary embodiment may be bonded directly below a unit of the holder 3 in the same manner as in the first exemplary embodiment.

### Other Examples of Modifications to Exemplary Embodiments

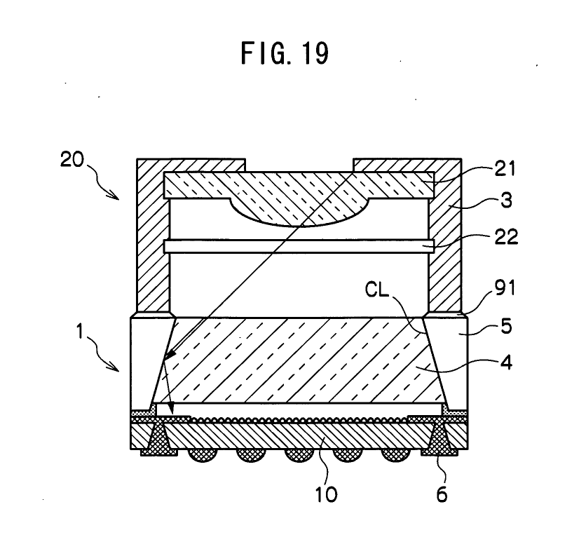

A modification of the first exemplary embodiment is configured, as shown in FIG. 18, with a sensor module 1 including a glass plate 4 that is a light transmitting chip, and a semiconductor chip 10 to which the glass plate 4 is attached by a bonding layer 9, and is similar to the camera module of FIG. 2 except in having a structure in which there is a multi-stepped surface profile to the side surfaces of the glass plate 4, for example two steps, and a light blocking resin layer 5 is provided over such a side surface.

In this sensor module 1 of the exemplary modification the side surfaces of the glass plate 4 can be formed in a stepped profile by using plural dicing blades of differing thicknesses in dicing process.

Another exemplary modification of the first exemplary embodiment is configured, as shown in FIG. 19, with a sensor module 1 including a glass plate 4 that is a light transmitting chip, and a semiconductor chip 10 to which the glass plate 4 is attached by a bonding layer 9, and is similar to the camera module of FIG. 2 except in having a structure in which the side surfaces of the glass plate 4 are not orthogonal to the main surface of the glass plate 4, and profiled as a collimator lens, and a light blocking resin layer 5 is provided over the side surfaces of the lens, these not being inclined instead of parallel to the optical axis.

In the sensor module of this exemplary modification, the side surfaces of the glass plate 4 can be formed into the sloped collimator lens by using in the dicing process a dicing blade in which the thickness of the dicing blade gradually thins on progression in the radial direction toward the outer peripheral end face thereof.

According to this exemplary modification the surface area of the light blocking resin layer 5 is increased, the choice of resin for use as the material of the holder of the lens unit and the material for the bonding member is increased, and the degrees of freedom for design of the camera module are increased.

Furthermore, when slope shaped side surfaces of the glass plate 4 of the exemplary modification are applied, the stray light (arrows in FIG. 19) the rate of reflection at the periphery of the photoreceptor portion 11 is raised, and a reduction in noise due to stray light can be expected.

What is claimed is:

1. A semiconductor device comprising:
a semiconductor chip having a penetrating electrode penetrating through from a first main surface of the semiconductor chip to a second main surface on the opposite side thereof, a photoreceptor portion formed on the first main surface, and a first wire at a periphery of the photoreceptor portion;
a light transmitting chip adhered to the first main surface at the periphery of the light transmitting chip, with a bonding layer interposed between the light transmitting chip and the first main surface, the light transmitting chip covering the light transmitting chip; and
a light blocking resin layer formed only on the side surfaces of the light transmitting chip and the bonding layer.

2. The semiconductor device of claim 1, wherein the light blocking resin layer has an outside surface that is orthogonal to the first main surface and the second main surface, and the outside surface is in the same flat plane as a side surface of the semiconductor chip.

3. The semiconductor device of claim 1, wherein the light blocking resin layer has an outside surface that is orthogonal to the first main surface and the second main surface, and the outside surface is parallel to a side surface of the light transmitting chip and to a side surface of the semiconductor chip.

4. The semiconductor device of claim 1, wherein the semiconductor chip has a second wire formed on the second main surface.

5. The semiconductor device of claim 1, wherein a metal pad is formed at a portion at the end of the penetrating electrode on the first main surface side.

6. The semiconductor device of claim 1, wherein the light transmitting chip is made from glass.
